(19) United States
(12) Patent Application Publication
(10) Pub. No.: US 2011/0214715 A1
(43) Pub. Date: Sep. 8, 2011

(54) SOLAR PANEL ASSEMBLY AND METHOD FOR PREPARING THEREOF

(75) Inventors: Harald Kahles, Stuttgart (DE); Stefan Grimm, Schwetzingen (DE); Heidi J. Hoglund, ST. Paul, MN (US); Kevin J. Reid, White Bear Lake, MN (US); David B. Malcolm, Maplewood, MN (US); John M. Zimmel, ST. Paul, MN (US)

(73) Assignee: H.B. Fuller Company, St. Paul, MN (US)

(21) Appl. No.: 13/040,197

(22) Filed: Mar. 3, 2011

Related U.S. Application Data
(60) Provisional application No. 61/310,843, filed on Mar. 5, 2010.
(60) Provisional application No. 61/310,792, filed on Mar. 5, 2010.
(60) Provisional application No. 61/310,904, filed on Mar. 5, 2010.
(60) Provisional application No. 61/310,916, filed on Mar. 5, 2010.
(60) Provisional application No. 61/310,928, filed on Mar. 5, 2010.

(30) Foreign Application Priority Data
Mar. 5, 2010 (DE) DE202010003295

(51) Int. Cl. H01L 31/048; H01L 31/18

(52) U.S. Cl. 136/251; 29/890.033

(57) ABSTRACT

The invention relates to a solar panel assembly and a method of making thereof. The solar panel assembly includes a solar panel having a non-light receiving surface and a support member. The support member is attached to the non-light receiving surface of the solar panel by means of a hot melt moisture curable composition.

This application claims priority to U.S. Ser. No. 61/310,843 filed Mar. 5, 2010, and German Utility Model Application No. DE202010003295, and U.S. Ser. No. 61/310,792, filed Mar. 5, 2010 and U.S. 61/310,904, filed Mar. 5, 2010, and U.S. Ser. No. 61/310,916, filed Mar. 5, 2010, and U.S. Ser. No. 61/310,928, filed Mar. 5, 2010, which are incorporated herein.

### BACKGROUND

The invention is directed to a solar panel assembly and a method for preparing thereof.

Solar panels are widely known in the art and are developed for the production of electricity from solar energy. Solar panels arranged on rooftops and on the ground in fields have unique requirements in that they must maintain the integrity under conditions of high humidity, because they are often positioned outdoors and exposed to rain, freezing rain, and snow and under conditions of widely varying temperature extremes, because they are often positioned in hot deserts, on hot asphalt rooftops, and in climates that experience extremely high temperatures, extremely low temperatures, and strong winds. Thus, any mechanism used to secure and maintain solar panels in a fixed position must function under a difficult set of environment conditions.

A solar panel has usually a planar, rectangular configuration and comprises a light receiving surface and a non-light receiving surface (underside). The thin film solar panel generally requires the attachment of some means of fixing the panel to a substructure and elements which reinforce the panel. Typically these functions are combined by attaching a backrail. Conventional crystalline silica cell based panels are typically framed both for stabilization and mechanical attachment to a substructure. Both types of panels can benefit from the present invention. In the prior art, solar panel and support member are assembled by means of flexible glue or a double-sided tape, see for example WO 2009/102772 A2.

Double-sided tape and flexible glue are costly and time consuming to apply. Often, the double-sided tape is to be applied onto the solar panel and/or the support member manually.

### SUMMARY OF THE INVENTION

In one aspect, the invention features a solar panel assembly comprising a solar panel having a non-light receiving surface and a support member, wherein the support member is attached to the non-light receiving surface of the solar panel by means of a hot melt moisture curable composition.

In another aspect, the invention relates to a method for preparing a solar panel assembly. The method includes applying a hot melt moisture curable composition onto a non-light receiving surface of a solar panel and/or a support member, and assembling the non-light receiving surface of the solar panel and the support member.

### BRIEF DESCRIPTION OF THE DRAWINGS

FIG. 1 is a schematic cross-sectional view of an inventive solar panel assembly.

FIG. 2 is an enlarged top view of a backrail as a support member of the inventive solar panel assembly as shown in FIG. 1.

### DETAILED DESCRIPTION OF THE INVENTION

The solar panel assembly of the invention includes a solar panel having a non-light receiving surface and a support member. The support member is attached to the non-light receiving surface of the solar panel through a hot melt moisture curable composition.

In one embodiment, suitable hot melt moisture curable composition includes a silane functional poly-cc-olefin polymer; a thermoplastic component having a softening point of at least 120° C. and selected from the group consisting of thermoplastic elastomers, thermoplastic polymers, and combinations thereof; a silane adhesion promoter having a flash point greater than 100° C. at atmospheric pressure and a boiling point greater than 100° C. at from 0.5 mmHg to 15 mmHg; optionally, a thermoplastic tackifying agent having a softening point greater than 80° C.; and optionally, a thermoplastic component having a softening point of less than 120° C., and selected from the group consisting of thermoplastic elastomers, thermoplastic polymers and combinations thereof.

In another embodiment, suitable hot melt moisture curable composition includes a silane functional poly-α-olefin polymer having a softening point of at least 120° C.; a silane adhesion promoter having a flash point greater than 100° C. at atmospheric pressure and a boiling point greater than 100° C. at from 0.5 mmHg to 15 mmHg; optionally, a thermoplastic component having a softening point of less than 120° C., and selected from the group consisting of thermoplastic elastomers, thermoplastic polymers and combinations thereof; and optionally, a thermoplastic tackifying agent having a softening point greater than 80° C. In one embodiment, the hot melt moisture curable composition further includes a thermoplastic component having a softening point of at least 120° C., and selected from the group consisting of thermoplastic elastomers, thermoplastic polymers and combinations thereof.

Other detailed information regarding the suitable hot melt moisture curable composition can be found in copending PCT International Patent Application No. PCT/US2011/27003, filed on Mar. 3, 2011 and entitled “Thermally resistant reactive silane functional poly-α-olefin hot melt adhesive composition, methods of using the same, and solar panel assembly including the same”, which is incorporated by reference in its entirety.

In one embodiment, suitable hot melt moisture curable composition includes a one-part, moisture curable hot melt adhesive composition including a thermoplastic polymer having a softening point of at least 120° C.; an atmospheric curing prepolymer; and a silane adhesion promoter having a flash point greater than 100° C. at atmospheric pressure and a boiling point greater than 100° C. at from 0.5 mmHg to 15 mmHg.

In one embodiment, the thermoplastic polymer having a softening point of at least 120° C. includes a polyester polyether block copolymer having a softening point of at least 120° C. In one embodiment, the polyester polyether block copolymer having a softening point of at least 120° C. is a hydroxy functional polyester polyether block copolymer having a hydroxyl number of from 2 mg KOH/g to 50 mg KOH/g.

In one embodiment, the atmospheric curing prepolymer includes a polyisocyanate prepolymer that includes the reaction product of a polyisocyanate and at least one of a polyether polyol, a polyester polyol, and combination thereof.

In one embodiment, the hot melt moisture curable adhesive composition further includes a tackifying agent, a thermoplastic polymer having a sating point of less than 120° C., and combinations thereof.

Other detailed information regarding the suitable hot melt moisture curable adhesive composition can be found in the copending PCT International Patent Application No. PCT/US2011/27045, filed on Mar. 3, 2011 and entitled “Thermally Resistant Hot Melt Moisture Cure Polyurethane Adhesive Composition, Methods of Using the Same, and Solar Panel Assembly Including the Same”, which is incorporated by reference in its entirety.

In one embodiment, the hot melt moisture curable composition contains spacer elements of a preferably defined geometry, preferably defined diameter.

In one embodiment, the spacer elements are spheres, cylinders, tubes, strips or ropes. The spacer elements may be, e.g., rubber balls of appropriate dimension. In one embodiment, the spacer elements are compressible. If the spacer elements are somewhat compressible, i.e. non rigid, the spacer elements do not give rise to point loads which could cause the solar panel (glass) to crack or break.

In one embodiment, the support member is a backrail. Such backrail is typically a roll formed galvanized steel profile, however also aluminum extrusions, stainless steel profiles or even profiles of non metal materials can be chosen. Respective backrails are well-known in the art.

The hot melt moisture curable composition may be applied in the form of at least one bead, or two beads, preferably multiple substantially parallel beads.

In one embodiment, the beads are either continuous or non-continuous.

In one embodiment, a distance of at least 1 mm between two adjacent beads is provided in order to form a channel.

In one embodiment, at least one end of the channel is provided with a cover, preferably a cap.

The material of the cover is most preferably gas permeable. In one embodiment, the cover is a gas permeable hot melt composition, as, e.g., those disclosed in U.S. Pat. No. 5,869,593, U.S. Pat. No. 5,851,661 and U.S. Pat. No. 6,133,400.

In a further embodiment, the hot melt moisture curable composition is flush with edges of the support member.

In another aspect, the invention features a method for preparing a solar panel assembly. The method includes applying a hot melt moisture curable composition onto a non-light receiving surface of a solar panel and/or a support member, and assembling the non-light receiving surface of the solar panel and the support member through the hot melt moisture curable composition.

In one embodiment, the hot melt moisture curable composition is applied ahead of time to at least one of the non-light receiving surface of the solar panel and the support member, and then cooled to solidify. During the assembling process, the pre-applied and solidified hot melt moisture curable composition is re-melted prior to or simultaneously with assembling the solar panel and the support member.

It is known in the art, that a hot melt moisture curable composition is melted by heating so that the composition can be easily applied. Thus, the hot melt moisture curable composition is considered to be cooled and set or solidified when its temperature falls to about ambient temperature and the composition is no longer in a liquid or semi-liquid form.

In some embodiments, the hot melt moisture curable composition is re-melted by radiation, conductivity, convection or induction, preferably by infrared radiation, microwave radiation, use of conductive fillers in the hot melt moisture curable composition and application of electric current, use of wire or metal component and application of electric current.

In one embodiment, spacer elements are added to the hot melt moisture curable composition prior to or after application of the hot melt moisture curable composition onto the non-light receiving surface of the solar panel and/or the support member.

Finally, it is possible to inject moist air or inert gas into the hot melt moisture curable composition prior to application so that the hot melt moisture curable composition can be used as a foam.

The inventors have discovered a solar panel assembly that can be prepared in a simple and cost effective manner and allows substantially full automation and improved productivity in its preparation process.

Surprisingly, it was found that the inventive solar panel assembly can be mounted in a very simple and cost effective manner. The invention allows for a higher degree of automation with reduced cost and improved productivity as the application of hot melt moisture curable composition does not need to be manually, but can be applied in an automation line for preparing solar panels. Also, the reproducibility of the inventive solar panel assembly is improved as the hot melt moisture curable composition will offer a resistance to compression thereby allowing a defined, reliable and sustainable spacing of the support member from the panel.

Further features and advantages of the invention can be derived from the following description, wherein preferred embodiments of the invention are explained in detail by way of examples on the basis of schematic drawings. It is, however, to be noted that the attached drawings only illustrate preferred embodiments of the invention and are therefore not to be construed to limit the scope of protection which is only defined by the accompanied claims.

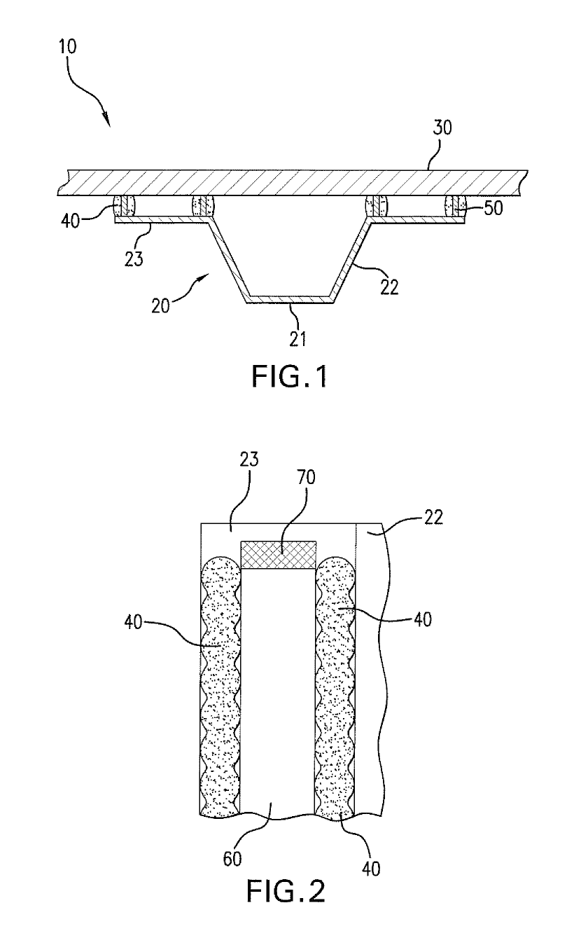

A solar panel assembly 10 of the present invention is shown in FIG. 1. The solar panel assembly 10 is supported from the non-light receiving surface via a support member 20. The support member 20 may have a V-shape including a lower mounting surface 21 for engagement with a mounting structure (not shown). Flexible support portions 22 extend upwardly and outwardly from structural mounting surface 21 in a V-shaped manner. Panel mounting portions 23 extend outwardly from each flexible support portion 22 and are configured to engage the non-light receiving surface of a solar panel 30. Two beads 40 of hot melt moisture curable composition are applied between the solar panel 30 and the support member 20 on each panel mounting portion 23. The hot melt moisture curable composition is preferably flush with the edges of the support member 20. This ensures that no moisture or other detrimental agents can accumulate in the interface.

Within the beads 40 spacer elements 50 are provided in the form of spheres which are preferably somewhat compressible up to a defined thickness. The spacer elements can be added to the hot melt moisture curable composition either prior to application of the composition onto the support member or the solar panel, or the spacer elements can be added to the already applied hot melt moisture curable composition. In the first alternative, it is necessary that the spacer elements can pass through an application nozzle of a glue gun or any other apparatus for application without clogging. In the second alternative it is essential that the spacer elements are inserted into the applied composition more or less immediately after application when the composition has not yet solidified.

In the embodiments in which spacers are included, the spacer elements provide additional resistance of the hot melt moisture curable composition to compression thereby allowing a defined, reliable and sustainable spacing of the support element from the solar panel, ensuring that any bond design criteria (for example thickness and area) are consistently met.

As also shown in FIG. 1, multiple hot melt moisture curable composition beads are applied to facilitate rapid and consistent cure of the composition compared to only one bead of the same total amount of the composition. Preferably, the beads are applied in such a way that after compression, i.e. attachment of the solar panel and the support member, a continuous channel or cavity, respectively, with a width of at least 1 mm is formed between adjacent beads. Preferably, at least one end of the channel can be covered, for example either with a cover as known in the art or with a pre-formed component. The material of the cover is preferably gas permeable to allow the exchange of water vapor but limits the ingress of contaminating particles or insects.

It is also preferred to inject moist air or inert gas into the hot melt moisture curable composition prior to application to ensure rapid cure and gap bridging in the case of a deformed support member.

The solar panel assembly according to the present invention can be prepared by applying hot melt moisture curable composition to either support member 20 or solar panel 30, or both, before placing the support member 20 on the solar panel 30. Of course, attachment of solar panel 30 and support member 20 is achieved by means of the hot melt moisture curable composition. No additional tape or other means is needed.

In one embodiment, it is possible to apply, in a first step, hot melt moisture curable composition onto the support member 20 or the solar panel 30, or both, without immediate assembly thereof. Rather, both, support member 20 and solar panel 30, can be stored separately (which requires significantly less storage space than that for a completed solar panel assembly 10). For assembly thereof, it is possible according to this preferred embodiment to re-melt the hot melt moisture curable composition. This can be achieved by e.g., radiation, conductivity, convection or induction. For example, solidified hot melt moisture curable composition that has been applied onto a support member 20 prior to assembling can be re-melted by simply heating, the support member 20. Or, the hot melt moisture curable composition may incorporate conductive fillers or wires or metal components of suitable resistivity. If a suitable electric current is applied, the heat will be generated within the hot melt moisture curable composition to provide a consistency of the composition, which allows assembly of the support member and the solar panel. After assembly thereof, the hot melt moisture curable composition can then solidify and cure.

FIG. 2 depicts an enlarged top view of a part of a support member onto which two substantially parallel beads 40 of hot melt moisture curable composition are applied. Between the beads a channel 60 or cavity, respectively, can be formed when attached to the solar panel. One end of that channel can be covered by a suitable cover or cap 70. The cover 70 in FIG. 2 is made of a gas permeable material to allow exchange of water vapor but limits the ingress of contaminating particles or insects.

In another embodiment the same function is achieved by the insertion of a suitable component that covers the cavity created by the multiple beads. Examples of the suitable components include a cylindrically formed mesh, an injection molded part, and a strip of fleece of appropriate dimensions. The component can be inserted across the ends of the composition beads prior to assembly.

A solar panel assembly according to the present invention can be prepared by methods including various steps known in the art. For example, such a method includes dispensing of the hot melt moisture curable composition onto the solar panel and/or the support member with a suitable dispensing apparatus that preferably can maintain a desired application temperature and ensures that a constant volume is dispensed. Further, the dispensing apparatus may include a suitable nozzle arrangement that can extrude desired bead shapes. Further, a positioning device can be provided that can apply the beads extruded from the nozzle arrangement. A handling function may assemble the coated component to the non-coated component in a consistent fashion. This could include a template or could consist of a robotic applicator. Also, a pressing function should be preferably provided that maintains the required pressure on the components to allow the hot melt moisture curable composition to wet the substrate surface.

As already mentioned above, in a preferred embodiment, the inventive method for preparing a solar panel assembly include the application of the hot melt moisture curable composition either to the solar panel and/or to the support member, or to both, without immediate assembly thereof. For example, the hot melt moisture curable composition can be applied first to the support member only. Then, the un-coated solar panel and the precoated support member can be stored, shipped, packaged or transported separately. This separation provides significant cost savings in transportation due to less required transportation space. The precoated support members can be re-melted immediately prior to assembly by bringing the support members in close proximity of the chosen re-melting device or apparatus. The energy is allowed to act on the pre-coated composition under such time as the composition melts thus reducing the surface tension thereby allowing wetting of the substrate (solar panel) to form the required adhesive bond.

According to this embodiment, it is also possible to apply the hot melt moisture curable composition in an automated fashion at an automation line, and then assemble the support member and the solar panel at a later stage.

In one preferred embodiment, the pre-coated support members can be irradiated with an infrared energy source for reactivation until the composition has undergone the required change in surface tension. The support members can then be immediately positioned and a pressure can be applied by means of a press to form the adhesive bond between the solar panel and the support member.

If support member and solar panel are not immediately assembled, it is preferred that after applying the hot melt moisture curable composition to the support member (and/or the solar panel), the contact to and presence of moisture is excluded. One preferred method would be to seal the pre-coated support member inside a moisture impermeable bag under vacuum or a dry protective gas. In a further embodiment, the pre-coated area of the support member (and/or the solar panel) can be covered by an impermeable strip that can be removed prior to re-melting and assembly.

The features disclosed in the foregoing description, in the claims and the drawings may, both separately and in any combination thereof, be material for realizing the invention in diverse forms thereof.

What we claim is:

1. A solar panel assembly, comprising a solar panel having a non-light receiving surface and a support member wherein the support member is attached to the non-light receiving surface of the solar panel by means of hot melt moisture curable composition.

2. The solar panel assembly according to claim 1, wherein the hot melt moisture curable composition comprises spacer elements of a defined geometry.

3. The solar panel assembly according to claim 2, wherein the spacer elements are spheres, cylinders, tubes, strips or ropes.

4. The solar panel assembly according to claim 2, wherein the spacer elements are compressible.

5. The solar panel assembly according to claim 1, wherein the hot melt moisture curable composition is a one-part, hot melt moisture curable adhesive composition comprising
a thermoplastic polymer having a softening point of at least 120° C.;
an atmospheric curing prepolymer; and
a silane adhesion promoter having a flash point greater than 100° C. at atmospheric pressure and a boiling point greater than 100° C. at from 0.5 mmHg to 15 mmHg; and
optionally, a thermoplastic tackifying agent having a softening point greater than 80° C.

6. The solar panel assembly according to claim 5, wherein the thermoplastic polymer is a polyester polyether block copolymer that includes a hydroxy functional polyester polyether block copolymer having a hydroxyl number of from 2 mg KOH/g to 50 mg KOH/g.

7. The solar panel assembly according to claim 5, wherein the atmospheric curing prepolymer comprises a polyisocyanate prepolymer.

8. The solar panel assembly according to claim 1, wherein the hot melt moisture curable composition is a moisture curable adhesive composition comprising:
a silane functional poly-α-olefin polymer;
a thermoplastic component having a softening point of at least 120° C. and selected from the group consisting of thermoplastic elastomers, thermoplastic polymers and combinations thereof;
a silane adhesion promoter having a flash point greater than 100° C. at atmospheric pressure and a boiling point greater than 100° C. at from 0.5 mmHg to 15 mmHg; and
optionally, a thermoplastic tackifying agent having a softening point greater than 80° C.

9. A method for preparing the solar panel assembly of claim 1, comprising applying the hot melt moisture curable composition onto the non-light receiving surface of the solar panel and/or the support member, and assembling the non-light receiving surface of the solar panel and the support member through the hot melt moisture curable composition.

10. The method according to claim 9, wherein the hot melt moisture curable composition is applied in the form of at least one, or two, or preferably multiple substantially parallel beads.

11. The method according to claim 10, wherein the beads are applied either continuously or non-continuously.

12. The method according to claim 10 wherein the melt moisture curable composition is applied in the form of at least two substantially parallel beads and a distance of at least 1 mm between two adjacent beads is provided to form a channel.

13. The method according to claim 12, wherein at least one end of the channel is provided with a cover.

14. The method according to claim 13, wherein the cover is gas permeable.

15. The method according to claim 9, wherein the hot melt moisture curable composition is flush with edges of the support member.

16. The method according to claim 9, wherein the hot melt moisture curable composition is pre-applied and cooled to solidify prior to the assembling.

17. The method according to claim 16, wherein the pre-applied hot melt moisture curable composition is re-melted prior to or simultaneously with assembling the solar panel and the support member.

18. The method according to claim 17 wherein re-melt is by radiation, conductivity, convection or induction, preferably by infrared radiation, microwave radiation, use of conductive fillers in the hot melt moisture curable composition and application of electric current, use of wire or metal component and application of electric current.

19. The method according to claim 9, wherein spacer elements are added to the hot melt moisture curable composition prior to or after application of the composition onto the non-light receiving surface of the solar panel and/or the support member.

20. The method according to claim 9, wherein moist air or inert gas is injected into the hot melt moisture curable composition prior to application.
